(19) United States
(12) Patent Application Publication
(10) Pub. No.: US 2026/0198103 A1
(43) Pub. Date: Jul. 9, 2026

(54) Photovoltaic Modules with Perimeter Terminals and Source Circuits

(71) Applicant: DISTRIBUTED ENERGY PRODUCTS LLC, Ponte Vedra, FL (US)

(72) Inventor: Daniel Edward Paul, Ponte Vedra, FL (US)

(73) Assignee: DISTRIBUTED ENERGY PRODUCTS LLC, Ponte Vedra, FL (US)

(21) Appl. No.: 19/008,750

(22) Filed: Jan. 3, 2025

(51) Int. Cl. H10F 19/90

(52) U.S. Cl. CPC H10F 19/904

(57) ABSTRACT

The present disclosure presents a photovoltaic module comprising at least one positive terminal disposed on a first side and at least one negative terminal disposed on a second, opposing side. The at least one positive terminal and the at least one negative terminal are each configured to reach an associated terminal of an opposing polarity.

### FIELD OF THE INVENTION

The present disclosure pertains to the field of art of photovoltaic systems, which convert solar energy into electrical energy. More specifically, the disclosure pertains to the electrical interconnection of photovoltaic modules within a photovoltaic system. The disclosure provides a special interconnection means that reduces the length of the wiring between the photovoltaic modules, thereby lowering the costs and complexity of the installation. The disclosure is applicable to any photovoltaic system that requires interconnection of photovoltaic modules.

### PRIOR ART

Conventional photovoltaic modules have junction boxes, source circuit cables of significant length, or both on the rear side of the module to connect two or more photovoltaic modules together or to link the photovoltaic array to a common connection point. The source circuit connection is usually done by a single fixed junction box, located within the photovoltaic module's boundary, and source circuit cables of a fixed length used to connect adjacent photovoltaic modules. These current methods can result in excessive circuit length, which lowers the system efficiency and increases the material and installation cost, especially for large-scale photovoltaic systems.

### SUMMARY OF THE INVENTION

The following is a concise summary of the disclosure presented herein with the primary aim of providing a preliminary understanding of certain aspects of the disclosure. It should be noted, however, that this summary is not intended to serve as a comprehensive overview of the disclosure, nor does it seek to identify or describe any critical or significant elements of the disclosure or the boundaries of its scope. Its sole purpose is to provide a rudimentary understanding of the disclosure's concepts and features, which will be expounded upon in greater detail in the ensuing sections.

In some embodiments, the photovoltaic module comprises at least one positive terminal and at least one negative terminal disposed on a perimeter of the module. The at least one positive terminal and the at least one negative terminal are each configured to reach an associated terminal of an opposing polarity.

In some embodiments, a photovoltaic assembly comprises at least one photovoltaic module including at least one positive terminal and at least one negative terminal disposed on a perimeter of the module; and at least one photovoltaic source circuit. The at least one photovoltaic source circuit includes at least one photovoltaic source circuit positive terminal and at least one photovoltaic source circuit negative terminal disposed on a perimeter of the module. The at least one photovoltaic module positive terminal is configured for connection with the at least one photovoltaic source circuit negative terminal and the at least one photovoltaic module negative terminal is configured for connection with the at least one photovoltaic source circuit positive terminal.

In some embodiments, the photovoltaic assembly comprises at least one photovoltaic module including at least one photovoltaic module positive terminal disposed on a first side; at least one positive terminal housing configured to enclose the at least one positive terminal; at least one photovoltaic module negative terminal disposed on a second, opposing side; at least one negative terminal housing configured to enclose the at least one negative terminal; and at least one photovoltaic source circuit comprising a wire. The wire includes at least one photovoltaic source circuit positive terminal disposed on a first side; at least one photovoltaic source circuit negative terminal disposed on a second, opposing side; at least one photovoltaic source circuit positive terminal housing configured to enclose the at least one photovoltaic source circuit positive terminal; and at least one photovoltaic source circuit negative terminal housing configured to enclose the at least one photovoltaic source circuit negative terminal. The at least one photovoltaic source circuit positive terminal housing is configured to mate with the at least one negative module terminal housing, and the at least one photovoltaic source circuit negative terminal housing is configured to mate with the at least one positive module terminal housing. The at least one photovoltaic module positive terminal is configured for connection with the at least one photovoltaic source circuit negative terminal and the at least one photovoltaic module negative terminal is configured for connection with the at least one photovoltaic source circuit positive terminal.

The present disclosure pertains to a photovoltaic module designed for streamlined and efficient connection with other photovoltaic modules to form photovoltaic arrays. The photovoltaic module features a plurality of terminals strategically positioned around its perimeter, each terminal advantageously bearing a specific polarity and advantageously engineered to accommodate a source circuit.

These terminals are arranged in a configuration that facilitates connection with one or more adjacent photovoltaic modules on multiple sides, advantageously allowing for flexible photovoltaic array configurations tailored to specific project requirements. Notably, the source circuits advantageously utilized possess minimal length, thereby reducing wiring costs, complexity, and enhancing the overall visual appeal of the photovoltaic array.

To ensure safety and prevent damage, the terminals are configured to prevent direct connections between terminals of the same polarity, advantageously effectively averting short-circuiting. Moreover, robust design considerations shield the terminals from environmental factors like moisture, dust, corrosion, and mechanical stress, thereby advantageously prolonging module lifespan and performance.

Furthermore, the terminals are engineered to minimize the risk of accidental contact with humans or animals, advantageously bolstering the safety profile of the photovoltaic array. In summary, the photovoltaic module outlined in this disclosure advantageously delivers a straightforward, adaptable, and dependable solution for interconnecting photovoltaic modules across diverse applications.

The above features and advantages will become apparent from the following detailed description taken with the accompanying drawings.

### BRIEF DESCRIPTION OF DRAWINGS

FIG. 1 illustrates a front perspective view of a non-limiting exemplary embodiment (the “exemplary embodiment”) of a photovoltaic module.

FIG. 2 illustrates a side view of the photovoltaic module.

FIG. 3 illustrates a back view of the photovoltaic module including plurality of photovoltaic module terminals positioned around the photovoltaic module perimeter.

FIG. 4 illustrates a schematic view of the photovoltaic module and photovoltaic source circuit.

FIG. 5 illustrates various schematic views of the photovoltaic module arranged with even cell string columns parallel to the perimeter bus and odd or even cell string rows perpendicular to the perimeter bus.

FIG. 6 illustrates various schematic views of the photovoltaic module arranged with odd or even cell string columns parallel to the perimeter bus and odd cell string rows perpendicular to the perimeter bus.

FIG. 7 illustrates a plan and section view of the photovoltaic module and photovoltaic source circuit.

FIG. 8 illustrates a back view of the photovoltaic module with a schematic overlay.

FIG. 9 illustrates an enlarged view of the photovoltaic module terminals and photovoltaic module terminal housings.

FIG. 10 illustrates the photovoltaic source circuit, photovoltaic source circuit terminals, photovoltaic source circuit terminal housings, and photovoltaic array source circuit terminal housings.

FIG. 11 illustrates an enlarged view of the photovoltaic module terminal housings and photovoltaic source circuit.

FIG. 12 illustrates a photovoltaic array of photovoltaic modules and photovoltaic source circuits.

### NUMBERING REFERENCE

1—Photovoltaic Array
2—Photovoltaic Module
3—Photovoltaic Cell
4—Photovoltaic Source Circuit
5—Photovoltaic Module Main Positive Bus
6—Photovoltaic Module Main Negative Bus
7—Photovoltaic Module Perimeter Positive Bus
8—Photovoltaic Module Perimeter Negative Bus
9—Photovoltaic Module Bypass Diode
10—Photovoltaic Module Positive Terminal Housing
11—Photovoltaic Module Negative Terminal Housing
12—Photovoltaic Module Positive Terminal
13—Photovoltaic Module Negative Terminal
14—Photovoltaic Source Circuit Negative Terminal Housing
15—Photovoltaic Source Circuit Positive Terminal Housing
16—Photovoltaic Source Circuit Negative Terminal
17—Photovoltaic Source Circuit Positive Terminal
18—Photovoltaic Array Source Circuit Positive Terminal Wire
19—Photovoltaic Array Source Circuit Negative Terminal Wire
20—Photovoltaic Array Source Circuit Positive Terminal Wire Housing
21—Photovoltaic Array Source Circuit Negative Terminal Wire Housing

### DETAILED DESCRIPTION OF THE INVENTION

The following detailed description and accompanying drawings provide a comprehensive disclosure of an exemplary embodiment for the purpose of facilitating one of ordinary skill in the relevant art to make and use the invention. As such, the detailed description and illustration of the one or more exemplary embodiments presented herein are purely exemplary in nature and are not intended to limit the scope of the invention or its protection in any matter. It is further noted that the drawings may not be to scale, and in some cases, certain details may be omitted which are not necessary for an understanding of the present invention, such as conventional details of fabrication and assembly. Furthermore, there is no intention to be bound by any expressed or implied theory presented in the preceding technical field, background, brief summary or the following detailed description.

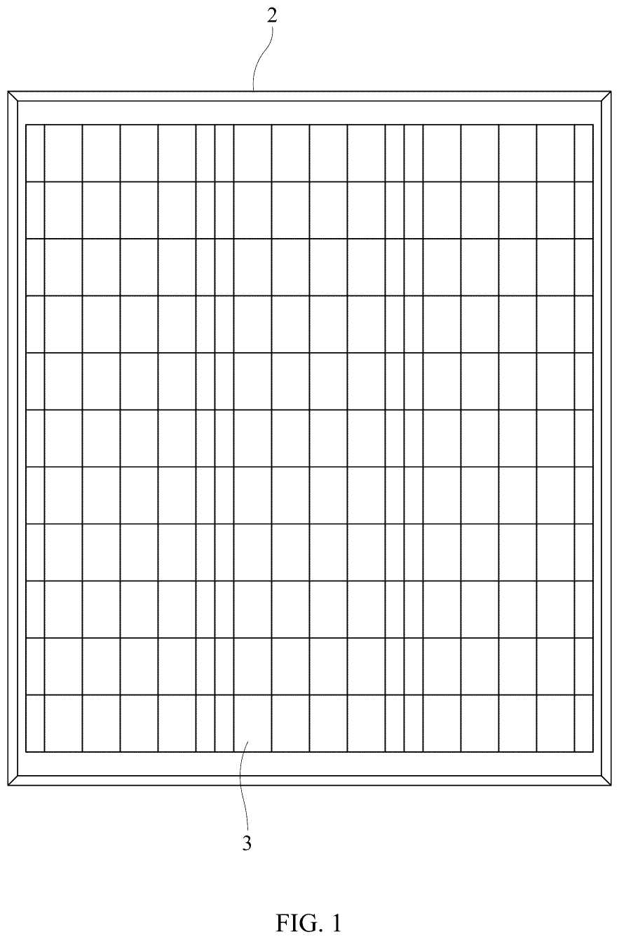

For purposes of description herein, the terms “upper”, “lower”, “left”, “rear”, “right”, “front”, “vertical”, “top”, “bottom” , “side” and derivatives thereof shall relate to the device as oriented in FIG. 1. Furthermore, there is no intention to be bound by any expressed or implied theory presented in the preceding technical field, background, brief summary or the following detailed description.

Photovoltaic modules are essential components of solar energy systems, converting sunlight into electrical energy. To maximize the efficiency and effectiveness of an area including multiple photovoltaic modules, it is crucial to ensure easy and efficient interconnection between photovoltaic modules. The following discloses providing a photovoltaic module designed for seamless connection with other photovoltaic modules to form photovoltaic arrays.

A non-limiting, exemplary embodiment (herein after as the “exemplary embodiment”) of a photovoltaic module 2 is disclosed herein. The exemplary embodiment of the photovoltaic module 2 may be connected to other photovoltaic modules to form a photovoltaic array. The disclosed photovoltaic module 2 is configured for connection with one or more source circuits that include short connecting wires. In addition, the disclosed photovoltaic module 2 includes housing around its terminal to prevent environmental damage to the terminals. Moreover, the disclosed photovoltaic module 2 has terminals positioned thereon to prevent direct connections.

FIG. 1 illustrates a front view of the photovoltaic module 2 according to the exemplary embodiment. As shown in FIG. 1, the photovoltaic module 2 comprises a plurality of photovoltaic cells 3 arranged in rows and columns forming a grid. As shown in FIG. 1, rows of the photovoltaic module 2 include fourteen photovoltaic cells 3 and columns of the photovoltaic module 2 include eleven photovoltaic cells 3, although the photovoltaic module 2 can include any suitable number of photovoltaic cells 3. The photovoltaic cells 3 are electrically connected in series or parallel to achieve a predetermined voltage and current output. The photovoltaic module 2, as shown in FIG. 1, has a rectangular shape, although any suitable shape is contemplated.

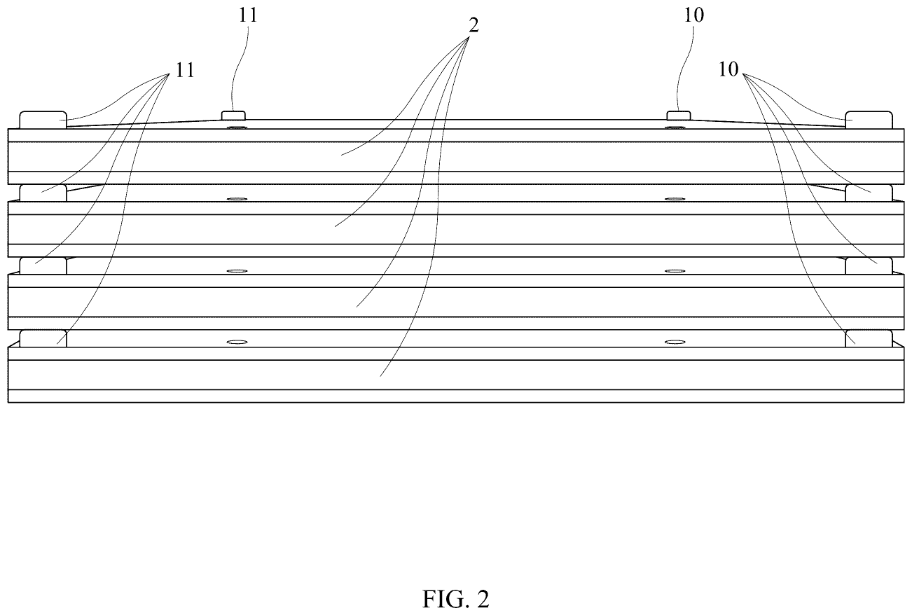

FIG. 2 illustrates a side view of four photovoltaic modules 2. Each photovoltaic module 2 includes one or more photovoltaic module positive terminal housings 10 that house a corresponding number of positive terminals (not shown in FIG. 2) and one or more photovoltaic module negative terminal housings 11 that house a corresponding number of negative terminals (not shown in FIG. 2). The photovoltaic module positive terminal housings 10 and the photovoltaic module negative terminal housings 11 can be distributed along a perimeter of the corresponding photovoltaic module 2. Each photovoltaic module 2 in the array can include the same number of photovoltaic module positive terminal housings 10 and photovoltaic module negative terminal housings 11 to ensure uniformity, and to facilitate versatile connectivity options. For storage or packaging purposes, the photovoltaic modules 2 may be arranged as a stack.

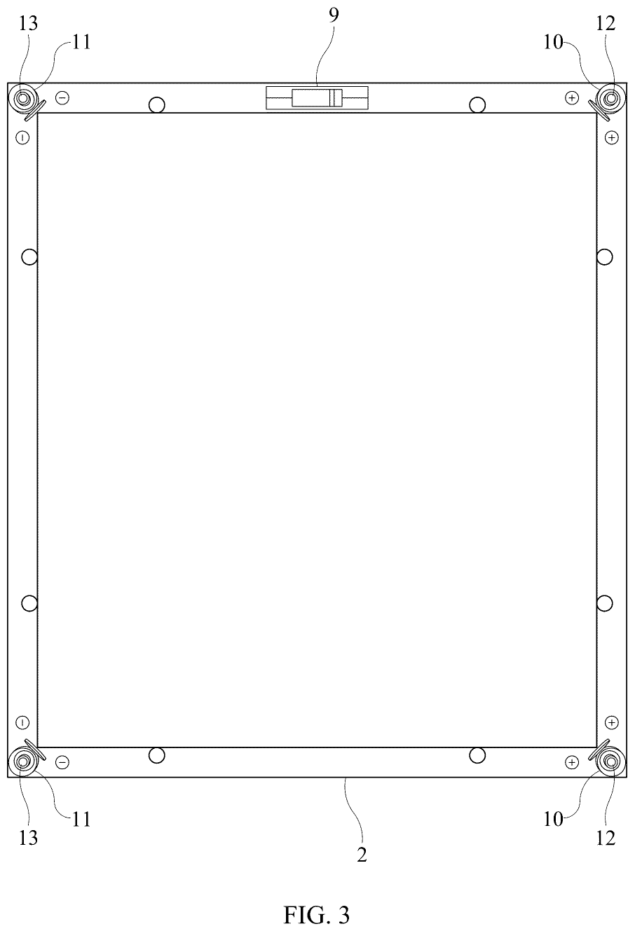

FIG. 3 illustrates a back view of the photovoltaic module 2. The photovoltaic module 2 includes one or more photovoltaic module positive terminals 12 and one or more photovoltaic module negative terminals 13 positioned around a perimeter of the photovoltaic module 2. As shown in FIG. 3, the photovoltaic module 2 includes two photovoltaic module positive terminals 12 and two photovoltaic module negative terminals 13, although the photovoltaic module 2 can include any suitable number of photovoltaic module positive terminals 12 and photovoltaic module negative terminals 13. Moreover, the photovoltaic module positive terminals 12 are disposed on a first half of the photovoltaic module 2 and the photovoltaic module negative terminals 13 are disposed on a second, opposing half of the photovoltaic module 2. As shown in FIG. 3, the photovoltaic module positive terminals 12 are disposed on a “right” half of the photovoltaic module 2, and the photovoltaic module negative terminals 13 are disposed on a “left” half of the photovoltaic module 2. It will be appreciated that the photovoltaic module positive terminals 12 and the photovoltaic module negative terminals 13 can be positioned around the perimeter of the photovoltaic module 2 so long as the photovoltaic module positive terminals 12 and the photovoltaic module negative terminals 13 are on opposing sides of the photovoltaic module 2. As shown in FIG. 3, the photovoltaic module positive terminals 12 are positioned in the “upper right” and the “lower right” corners of the photovoltaic module 2, and the photovoltaic module negative terminals 13 are positioned in the “upper left” and the “lower left” corners of the photovoltaic module 2, although the photovoltaic module positive terminals 12 and the photovoltaic module negative terminals 13 can be positioned along any other suitable portion (i.e., along a side edge) of the photovoltaic module 2, provided that the photovoltaic module positive terminals 12 and the photovoltaic module negative terminals 13 are positioned opposite from each other.

FIG. 3 also shows that each photovoltaic module positive terminal 12 is enclosed or housed by a corresponding photovoltaic module positive terminal housing 10, and each photovoltaic module negative terminal 13 is enclosed or housed by a photovoltaic module negative terminal housing 11. FIG. 3 also shows a photovoltaic module bypass diode 9 disposed between a pair of terminals that include one photovoltaic module positive terminal 12 and one photovoltaic module negative terminal. 13.

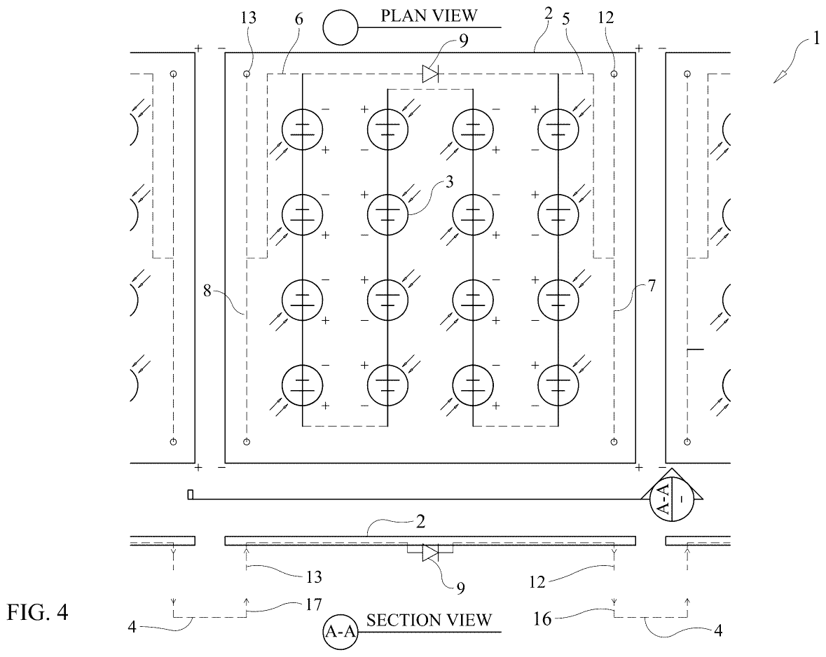

FIG. 4 shows a schematic plan and a section view of the photovoltaic module 2, and a schematic plan and a section view of multiple photovoltaic modules 2 (three of which are shown in INSET A taken along line A-A of FIG. 4) connected with multiple photovoltaic source circuits 4 (two of which are shown in INSET A of FIG. 4, and are configured as wires) to form a photovoltaic assembly. As shown in FIG. 4, the photovoltaic cells 3 are connected in series to form a cell string of photovoltaic cells 3 (in a 4×4 grid as shown in FIG. 4). A negative end of the cell string of photovoltaic cells 3 is disposed at the “left” end of the photovoltaic module 2 where the photovoltaic module negative terminals 13 are disposed, and a positive end of the cell string of photovoltaic cells 3 is disposed at the “right” end of the photovoltaic module 2 where the photovoltaic module positive terminals 12 are disposed.

A photovoltaic module main positive bus 5 (shown in the “right” half of FIG. 4) can be routed from a positive end of the cell string of photovoltaic cells 3, and is connected to a photovoltaic module perimeter positive bus 7 (shown in the “right” half of FIG. 4). The photovoltaic module perimeter positive bus 7 is connected to both photovoltaic module positive terminals 12 located in the upper and lower “right” corners of the photovoltaic module 2. To reduce potential losses, which may occur due to unequal circuit lengths, and balance a circuit impedance between the photovoltaic module positive terminals 12, a connection point of the photovoltaic module main positive bus 5 connection to the photovoltaic module perimeter positive bus 7 can be located at a midpoint of the photovoltaic module perimeter positive bus 7. The photovoltaic module perimeter positive bus 7 is routed along the perimeter of the photovoltaic module 2, thereby minimizing a circuit length of the photovoltaic module 2 that traditionally includes junction boxes and source circuits located within the perimeter of the photovoltaic module 2. Advantageously, locating a connection of the photovoltaic module main positive bus 5 to the photovoltaic module perimeter positive bus 7 creates a circuit of equal length between any positive and negative module terminals, thereby effectively balancing the module circuit impedance (i.e., resistance). A length and an orientation of the photovoltaic module perimeter positive bus 7 is dependent on a location and quantity of photovoltaic module positive terminals 12. For instance, if the only one set of terminals were located middle center of the photovoltaic module 2, the length and orientation of the perimeter bus would be different than if the module terminals were located top and bottom center of the module, or if there were multiple module terminals located middle center and top/bottom center.

A photovoltaic module main negative bus 6 (shown in the “left” half of FIG. 4) can be routed from a negative end of the cell string of photovoltaic cells 3, and is connected to a photovoltaic module perimeter negative bus 8 (shown in the “left” half of FIG. 4). The photovoltaic module perimeter negative bus 8 is connected to both photovoltaic module negative terminals 13 located in the upper and lower “left” corners of the photovoltaic module 2. To reduce potential losses, which may occur due to unequal circuit lengths, and balance a circuit impedance between the photovoltaic module negative terminals 13, a connection point of the photovoltaic module main negative bus 6 connection to the photovoltaic module perimeter negative bus 8 can be located at a midpoint of the photovoltaic module perimeter negative bus 8. The photovoltaic module perimeter negative bus 8 is routed along the perimeter of the photovoltaic module 2, thereby minimizing a circuit length of the photovoltaic module 2 that traditionally includes junction boxes and source circuits located within the perimeter of the photovoltaic module 2. Advantageously, locating a connection of the photovoltaic module main negative bus 8 to the photovoltaic module perimeter negative bus 8 creates a circuit of equal length between any positive and negative module terminals, thereby effectively balancing the module circuit impedance (i.e., resistance). A length and an orientation of the photovoltaic module perimeter negative bus 8 is dependent on a location and quantity of photovoltaic module positive terminals 12. For instance, if the only one set of terminals were located middle center of the photovoltaic module 2, the length and orientation of the perimeter bus would be different than if the module terminals were located top and bottom center of the module, or if there were multiple module terminals located middle center and top/bottom center.

The photovoltaic module positive terminals 12 are positioned along photovoltaic module perimeter positive bus 7 to allow the photovoltaic module 2 to connect with one or more other the photovoltaic modules 2 at one or more sides thereof. The photovoltaic module negative terminals 13 are positioned along photovoltaic module perimeter negative bus 6 to allow the photovoltaic module 2 to connect with one or more other the photovoltaic modules 2 at one or more sides thereof.

The photovoltaic module bypass diode 9 is positioned between the photovoltaic module main positive bus 5 and the photovoltaic module main negative bus 6 to provide an alternative path for current flow when all (or part of) the photovoltaic module 2 is shaded or faulty.

As shown in INSET A of FIG. 4, a plurality of photovoltaic source circuits 4 are used to connect two or more photovoltaic modules 2 together, and to a common connection point of the photovoltaic array 1. The photovoltaic source circuits 4 are conductive, and include a photovoltaic source circuit negative terminal 16 on a first end thereof, and a photovoltaic source circuit positive terminal 17 on a second, opposing end thereof. The photovoltaic source circuit negative terminal 16 has a shape and a size that corresponds to a polarity of photovoltaic module positive terminals 12 to which the photovoltaic source circuit negative terminal 16 is connected. The photovoltaic source circuit positive terminal 17 has a shape and a size that corresponds to a polarity of photovoltaic module negative terminals 13 to which the photovoltaic source circuit positive terminal 17 is connected.

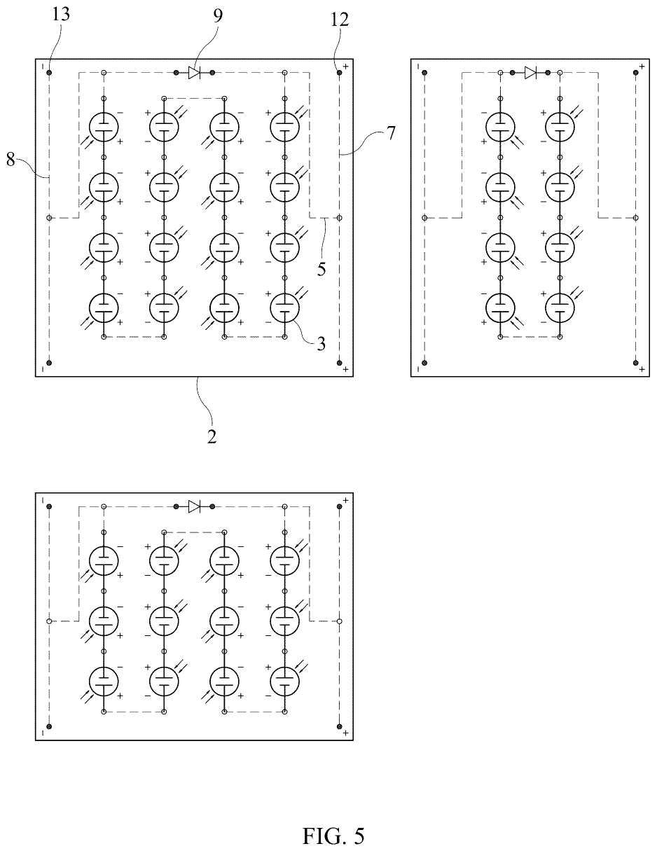

FIGS. 5A-5C illustrate various schematic views of the photovoltaic module 2 arranged with even cell string columns parallel to the perimeter bus and odd or even cell string rows perpendicular to the perimeter bus. FIGS. 5A-5C illustrate arrangements of photovoltaic cells 3 between the photovoltaic module main positive bus 5 and the photovoltaic module main negative bus 6. These arrangements allow for even cell string columns parallel to the photovoltaic module perimeter positive bus 7 and the photovoltaic module perimeter negative bus 8 while allowing odd or even cell string rows perpendicular to the photovoltaic module main positive bus 5 and the photovoltaic module main negative bus 6. This is significant to mention as it allows for odd or even cell string rows perpendicular to the photovoltaic module perimeter positive bus 7 and the photovoltaic module perimeter negative bus 8, thus allowing the photovoltaic cells 3 string to originate and terminate on the same side of the photovoltaic module 2. FIG. 5A shows a 4×4 grid of photovoltaic cells 3. FIG. 5B shows a 4×2 grid of photovoltaic cells 3. FIG. 5C shows a 3×4 grid of photovoltaic cells 3. It is anticipated that alternative arrangements of the photovoltaic cells 3 may be applied.

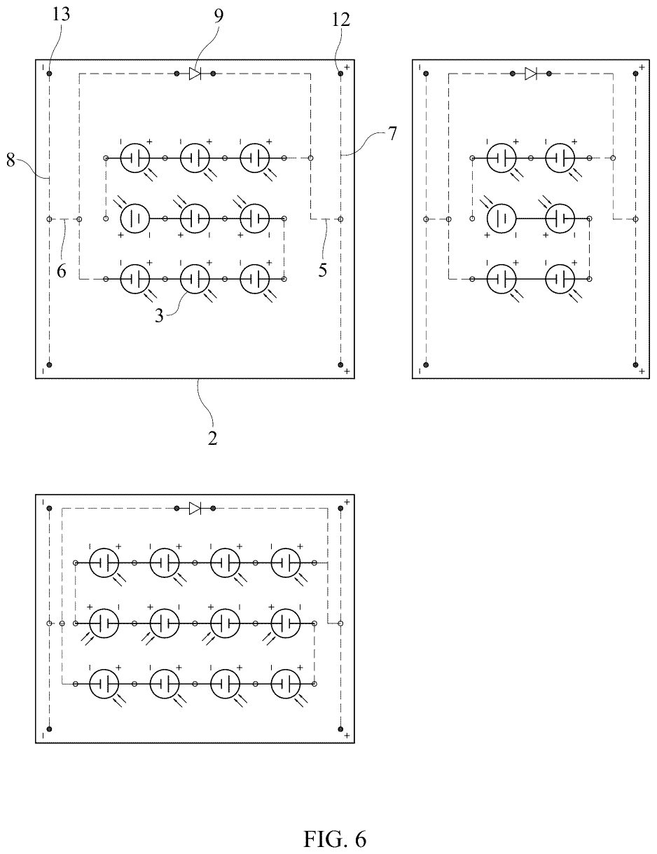

FIGS. 6A-6C illustrate various schematic views of the photovoltaic module 2 arranged with odd or even cell string columns parallel to the perimeter bus and odd cell string rows perpendicular to the perimeter bus. FIGS. 6A-6C illustrate arrangements of photovoltaic cells 3 between the photovoltaic module main positive bus 5 and the photovoltaic module main negative bus 6. These arrangements allow for odd cell string rows perpendicular to the photovoltaic module perimeter positive bus 7 and the photovoltaic module perimeter negative bus 8 while allowing odd or even cell string columns parallel to the photovoltaic module main positive bus 5 and the photovoltaic module main negative bus 6. This is significant to mention as it allows for odd or even cell string columns parallel to the photovoltaic module perimeter positive bus 7 and the photovoltaic module perimeter negative bus 8, thus allowing the photovoltaic cells 3 string to originate and terminate on the opposite side of the photovoltaic module 2. FIG. 6A shows a 3×3 grid of photovoltaic cells 3. FIG. 5B shows a 3×2 grid of photovoltaic cells 3. FIG. 5C shows a 3×4 grid of photovoltaic cells 3. It is anticipated that alternative arrangements of the photovoltaic cells 3 may be applied.

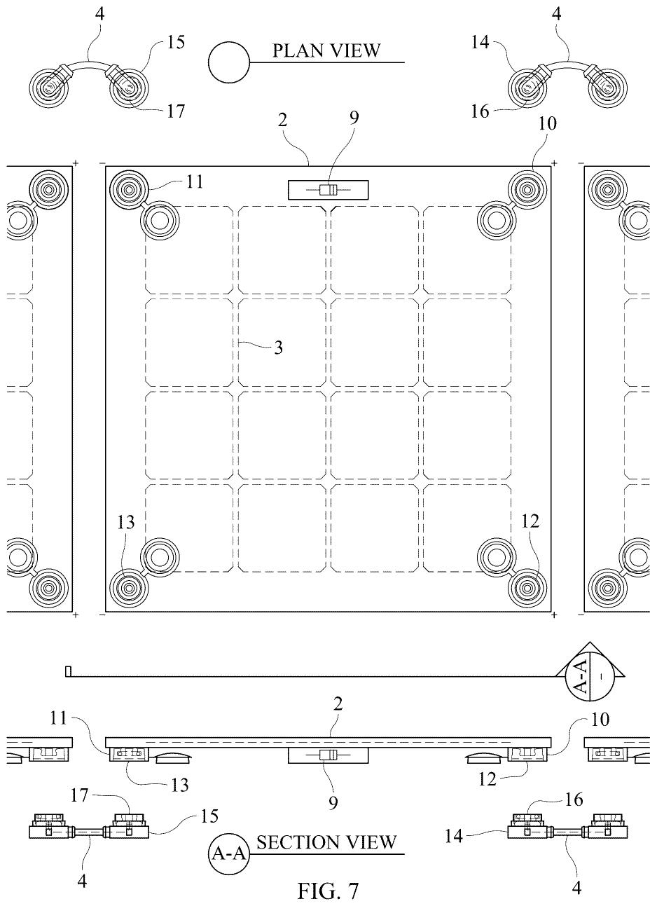

FIG. 7 shows a plan and section view of the photovoltaic module 2, and a plan and section view of multiple photovoltaic modules 2 (three of which are shown in INSET A taken along line A-A of FIG. 4) connected with multiple photovoltaic source circuits 4 (two of which are shown in INSET A of FIG. 7). As shown in FIG. 7, a “full” photovoltaic module 2 is shown in the middle of FIG. 7, while two “partial” photovoltaic modules 2 are shown on opposing sides of the full photovoltaic module 2. A “left” photovoltaic source circuit 4 is connected to a “left” side of the full photovoltaic module 2. The photovoltaic source circuit 4 are connected to the terminals of the photovoltaic module 2 in an opposing polarity arrangement, advantageously preventing short-circuiting and damage of the photovoltaic module 2. To do so, the photovoltaic source circuit positive terminal 17 of the “left” photovoltaic source circuit 4 is connected to the photovoltaic module negative terminal 13 of the full photovoltaic module 2. The photovoltaic source circuit negative terminal 16 of the “left” photovoltaic source circuit 4 is connected to the photovoltaic module positive terminal 12 of the “left-partial” photovoltaic module 2. The photovoltaic source circuit negative terminal 16 of the “right” photovoltaic source circuit 4 is connected to the photovoltaic module positive terminal 12 of the full photovoltaic module 2. The photovoltaic source circuit positive terminal 17 of the “right” photovoltaic source circuit 4 is connected to the photovoltaic module negative terminal 13 of the “right-partial” photovoltaic module 2. Stated another way, the positive terminals 17 of the photovoltaic source circuit 4 are connected to the negative terminals 13 of the photovoltaic module 2, and the negative terminals 16 of the photovoltaic source circuit 4 are connected to the positive terminals 12 of the photovoltaic module 2.

The photovoltaic module positive terminal housing 10 has an opening that allows for insertion of a corresponding photovoltaic source circuit negative terminal 16 thereinto. The photovoltaic module positive terminal housing 10 is configured to protect the photovoltaic module positive terminal 12 from the environmental conditions in which the photovoltaic module 2 are to be installed. The photovoltaic module positive terminal housing 10 is configured to prevent accidental contact with the photovoltaic module positive terminal 12. The photovoltaic module positive terminal housing 10 is configured to prevent direct connection with photovoltaic module positive terminal 12. The photovoltaic module positive terminal housing 10 is configured to prevent direct connection with photovoltaic source circuit positive terminal 17. The photovoltaic module positive terminal housing 10 has a locking mechanism that secures the photovoltaic source circuit negative terminal 16 to the photovoltaic module positive terminal housing 10.

The photovoltaic module negative terminal housing 11 has an opening that allows the insertion of the photovoltaic source circuit positive terminal 17 thereinto. The photovoltaic module negative terminal housing 11 is configured to protect the photovoltaic module negative terminal 13 from environmental conditions in which the photovoltaic module 2 is to be installed. The photovoltaic module negative terminal housing 11 is configured to prevent accidental contact with the photovoltaic module negative terminal 13. The photovoltaic module negative terminal housing 11 is configured to prevent direct connection with the photovoltaic module negative terminal 13. The photovoltaic module negative terminal housing 11 is configured to prevent direct connection with the photovoltaic source circuit negative terminal 16. The photovoltaic module negative terminal housing 11 has a locking mechanism that secures the photovoltaic source circuit positive terminal 17 to the photovoltaic module negative terminal housing 11.

The photovoltaic source circuit 4 has a length that is equal to or greater than the distance between the photovoltaic module positive terminal 12 and the photovoltaic module negative terminal 13 on the same side of an adjacent photovoltaic module 2.

The photovoltaic source circuit negative terminal 16 is enclosed in a photovoltaic source circuit negative terminal housing 14. The photovoltaic source circuit positive terminal 17 is enclosed in a photovoltaic source circuit positive terminal housing 15. The photovoltaic source circuit negative terminal housing 14 and the photovoltaic source circuit positive terminal housing 15 can be configured similarly as the photovoltaic module positive terminal housing 10 and the photovoltaic module negative terminal housing 11.

When the photovoltaic module 2 is connected to a photovoltaic source circuit 4, the photovoltaic source circuit negative terminal housing 14 mates with the photovoltaic module positive terminal housing 10 in a male-female arrangement to protect a connection between the corresponding photovoltaic source circuit negative terminal 16 and the photovoltaic module positive terminal 12. Similarly, the photovoltaic source circuit positive terminal housing 15 mates with the photovoltaic module negative terminal housing 11 in a male-female arrangement to protect a connection between the corresponding photovoltaic source circuit positive terminal 17 and the photovoltaic module negative terminal 13.

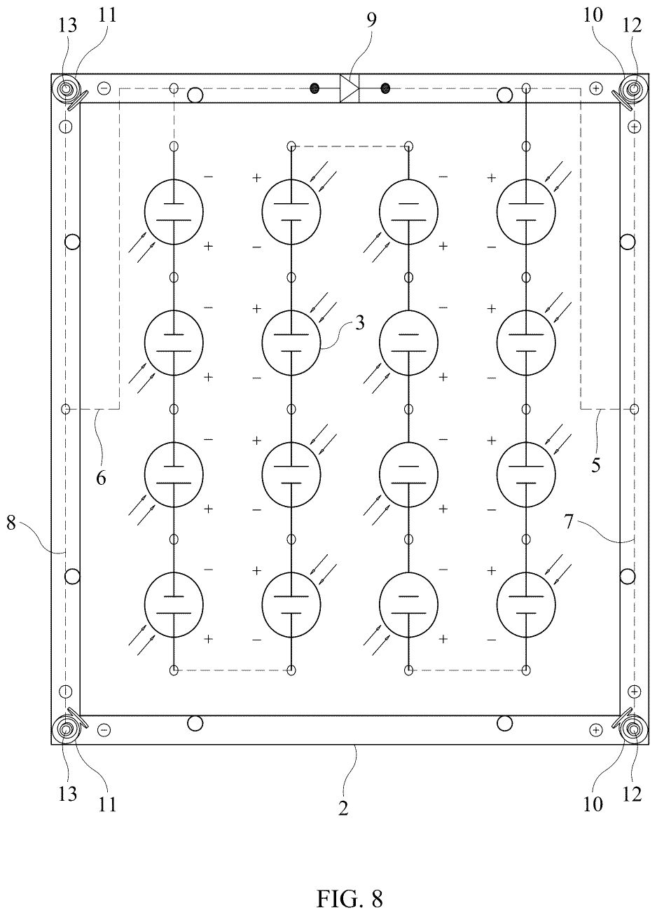

FIG. 8 illustrates a back view of the photovoltaic module 2 of FIG. 3 with the schematic overlay of the photovoltaic module 2 of FIG. 4. The description of FIGS. 3 and 4 will not be repeated for brevity and conciseness.

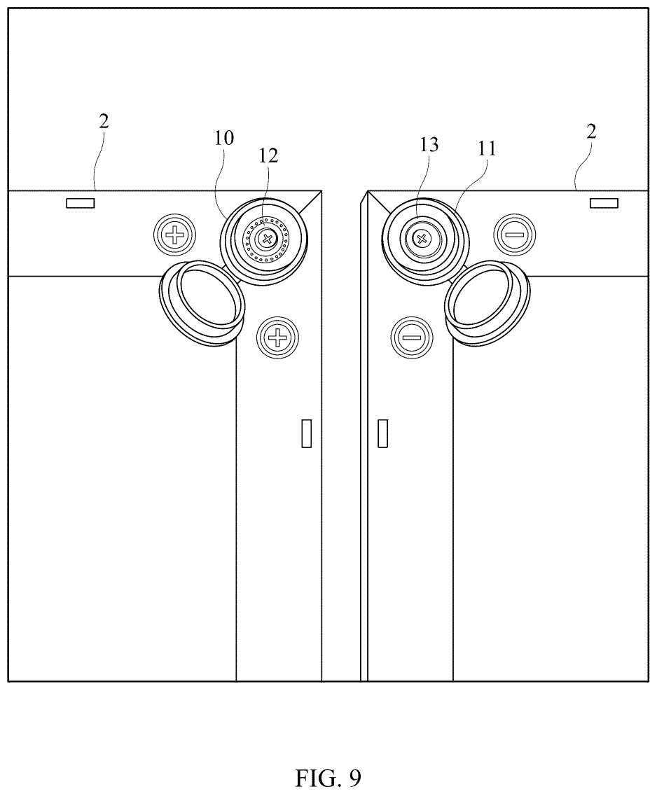

FIG. 9 illustrates an enlarged view of the photovoltaic module positive terminal housing 10 and the photovoltaic module negative terminal housing 11 including the corresponding photovoltaic module positive terminal 12 and the corresponding photovoltaic module negative terminal 13. The photovoltaic module positive terminal housing 10 is configured to (i) protect the photovoltaic module positive terminal 12 from the environmental conditions, (ii) prevent accidental contact with the photovoltaic module positive terminal 12, and (iii) prevent direct connection with the photovoltaic module positive terminal 12. Similarly, the photovoltaic module negative terminal housing 11 is configured to (i) protect the photovoltaic module negative terminal 13 from the environmental conditions, (ii) prevent accidental contact with the photovoltaic module negative terminal 13, and (iii) prevent direct connection with the photovoltaic module negative terminal 13.

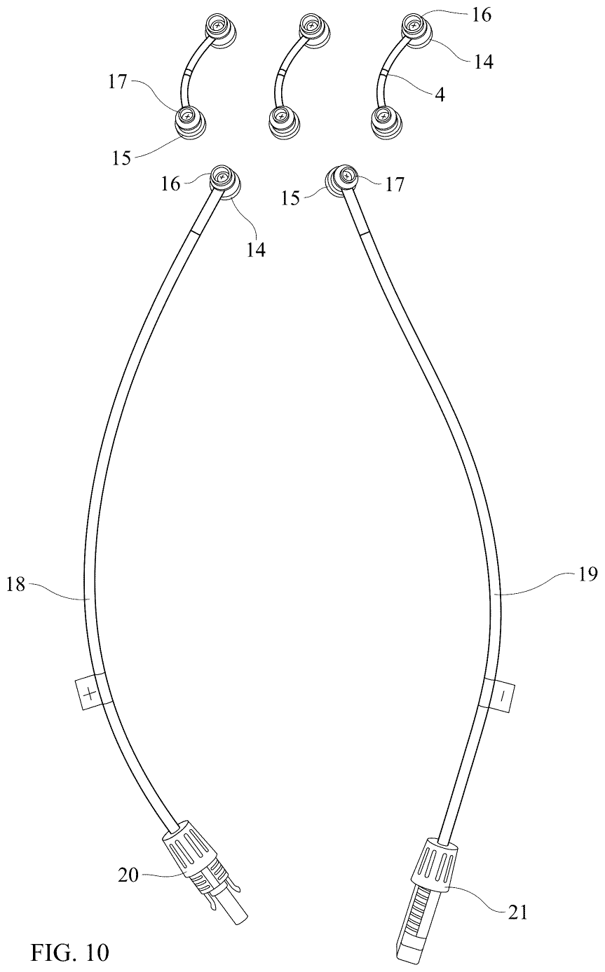

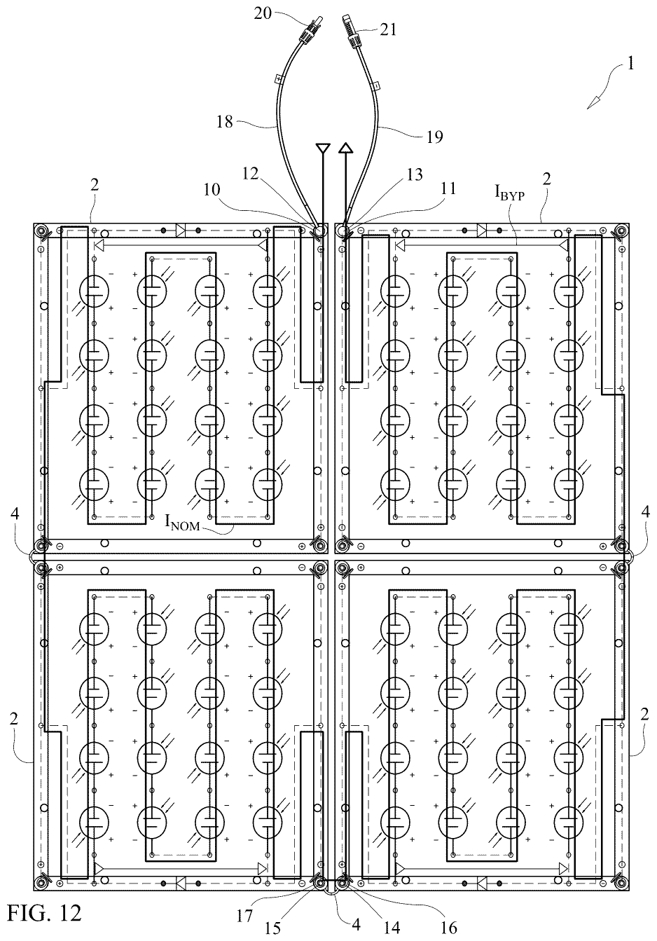

FIG. 10 illustrates the photovoltaic source circuit 4 with a photovoltaic array source circuit positive terminal wire 18 and a photovoltaic array source circuit negative terminal wire 19. The photovoltaic source circuit 4 is used to connect a first photovoltaic module 2 to a second photovoltaic module 2, while the photovoltaic array source circuit positive terminal wire 18 and the photovoltaic array source circuit negative terminal wire 19 are used to connect a photovoltaic array 1 to a common connection point of the photovoltaic array 1, as shown in FIG. 12.

The photovoltaic array source circuit positive terminal wire 18 includes the photovoltaic source circuit negative terminal 16 and photovoltaic source circuit negative terminal housing 14 at a first end thereof, and a photovoltaic array source circuit positive terminal housing 20 at a second end thereof. The photovoltaic array source circuit negative terminal wire 19 includes the photovoltaic source circuit positive terminal 17 and photovoltaic source circuit positive terminal housing 15 at a first end thereof, and a photovoltaic array source circuit negative terminal housing 21 at a second end thereof. The photovoltaic array source circuit positive terminal housing 20 and the photovoltaic array source circuit negative terminal housing 21 are configured to connect the photovoltaic array 1 (shown in FIG. 12) to an external structure (not shown), such as a combiner box, a converter, and so forth.

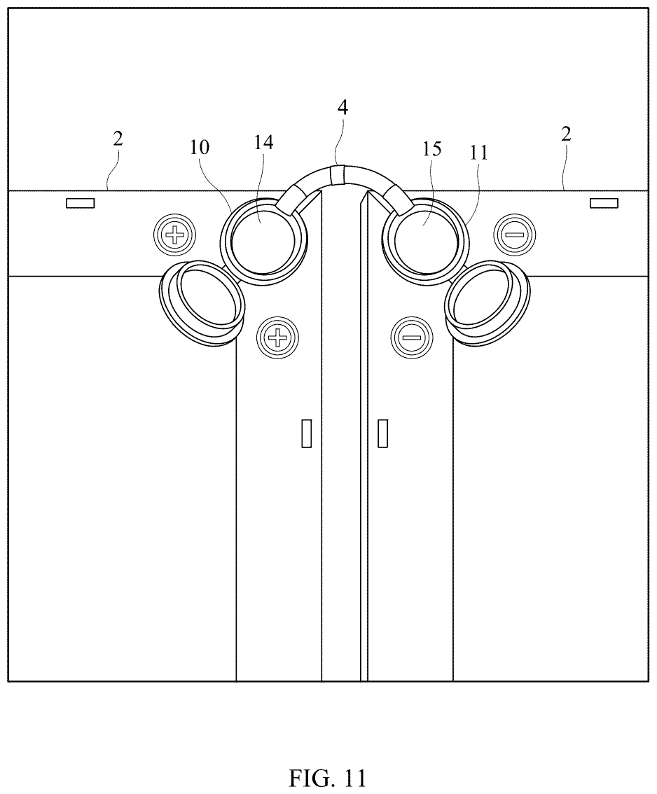

FIG. 11 illustrates an enlarged view of the photovoltaic source circuit 4 with the photovoltaic source circuit negative terminal housing 14 at a first end thereof, and the photovoltaic source circuit positive terminal housing 15 at a second end thereof. The photovoltaic source circuit 4 is connected to a corresponding photovoltaic module 2 at each end of the photovoltaic source circuit 4. The photovoltaic source circuit 4 has a length that is equal to or greater than the distance between the photovoltaic module positive terminal housing 10 and the photovoltaic module negative terminal housing 11 on the same side of adjacent photovoltaic modules 2.

FIG. 12 illustrates the photovoltaic array 1 of photovoltaic modules 2 (four of which are shown in FIG. 12) connected by corresponding photovoltaic source circuits 4. The photovoltaic source circuits 4 are used to connect a plurality of photovoltaic modules 2. The photovoltaic array source circuit positive terminal wire 18 and the photovoltaic array source circuit negative terminal wire 19 are used to connect the photovoltaic array 1 to a common connection point of a photovoltaic system (not shown) by means of the photovoltaic array source circuit positive terminal housing 20 and the photovoltaic array source circuit negative terminal housing 21, respectively.

Under normal conditions, a Conventional Nominal Current (I_{NOM}) flows through the photovoltaic array 1. Under abnormal conditions, for example, when a photovoltaic module 2 is shaded, a conventional Bypass Current (I_{BYP}) flows through the affected photovoltaic module 2.

Photovoltaic modules 2 can be interconnected using photovoltaic source circuits 4. These photovoltaic source circuits 4 have a length that is equal to or greater than the distance between the photovoltaic module positive terminal housing 10 and the photovoltaic module negative terminal housing 11 on the same side of adjacent photovoltaic modules 2, reducing wiring cost and complexity while enhancing the aesthetic appearance of the photovoltaic array 1. The photovoltaic modules 2 can be connected on one or more sides to each other, depending on the desired configuration of the photovoltaic array 1, thereby providing flexibility in system design and installation.

Each photovoltaic module terminal 12, 13 and photovoltaic source circuit terminal 16, 17 is designed to prevent direct connection with terminals of the same polarity, thereby mitigating the risk of short-circuiting and damage to the photovoltaic modules 2.

The photovoltaic module terminal housings 10, 11 and photovoltaic source circuit terminal housings 14, 15 are configured with protective features to shield them from environmental factors such as moisture, dust, corrosion, and mechanical stress. Additionally, the design of the photovoltaic module terminal housings 10, 11 and photovoltaic source circuit terminal housings 14, 15 prevent accidental contact with humans or animals, enhancing the safety of the photovoltaic array.

A spacing between photovoltaic module terminals 12, 13 is optimized to accommodate source circuit terminals 16, 17 while minimizing the footprint of the photovoltaic module 2.

The photovoltaic module terminals 12, 13 are strategically placed to facilitate interconnection with other photovoltaic modules 2 and components of a photovoltaic system. Each photovoltaic module terminal 12, 13 has a specific polarity and is adapted to receive a photovoltaic source circuit 16, 17 of opposite polarity.

The disclosed photovoltaic module 2 offers a simple, flexible, and reliable solution for interconnecting photovoltaic modules 2 in various applications. By incorporating strategically positioned photovoltaic module terminals, protective features, and efficient photovoltaic source circuits, the photovoltaic module 2 and its photovoltaic source circuits 4 facilitates assembly of photovoltaic arrays 1 while ensuring safety, durability, and optimal performance in diverse environmental conditions.

While the embodiments of the disclosure have been disclosed, certain modifications may be made by those skilled in the art to modify the disclosure without departing from the spirit of the disclosure.

1. A photovoltaic module, comprising:
a plurality of photovoltaic cells formed within a perimeter, and a separate continuous periphery spaced apart from and offset laterally outward from the perimeter of the plurality of photovoltaic cells and forming outer edges of the photovoltaic module;
at least one positive terminal and at least one negative terminal disposed completely within the periphery of the photovoltaic module and inwardly spaced from the outer edges of the photovoltaic module; and
wherein the at least one positive terminal and the at least one negative terminal are each configured to reach an associated terminal of an opposing polarity.

2. The photovoltaic module of claim 1, wherein the periphery of the photovoltaic module comprises a first side and a second, opposing side; and wherein the at least one positive terminal is disposed on the first side and the at least one negative terminal is disposed on the second side.

3. The photovoltaic module of claim 1, wherein the at least one positive terminal and the at least one negative terminal are disposed on opposing corners of the periphery of the photovoltaic module.

4. The photovoltaic module of claim 1, wherein:
the at least one positive terminal comprises two positive terminals, each positive terminal being disposed in corners on the first side of the periphery of the photovoltaic module; and
the at least one negative terminal comprises two negative terminals, each negative terminal being disposed in corners on the second, opposing side of the periphery of the photovoltaic module.

5. (canceled)

6. The photovoltaic module of claim 1, further comprising:
a perimeter positive bus connecting the at least one positive terminals; and
a main positive bus connecting the plurality of photovoltaic cells to the perimeter positive bus.

7. The photovoltaic module of claim 6, further comprising:
a perimeter negative bus connecting the at least one negative terminals; and
a main negative bus connecting the plurality of photovoltaic cells to the perimeter negative bus.

8. The photovoltaic module of claim 1, further including diode disposed between, and connecting, the main positive bus and the main negative bus.

9. The photovoltaic module of claim 1, further comprising:
at least one positive terminal housing configured to enclose the at least one positive terminal; and
at least one negative terminal housing configured to enclose the at least one negative terminal.

10. A photovoltaic assembly, comprising:
at least one photovoltaic module including:
a plurality of photovoltaic cells forming a perimeter, and an outer periphery spaced apart from and offset laterally outward from the perimeter of the plurality of photovoltaic cells;
at least one positive terminal and at least one negative terminal disposed and contained within outer edges formed by the periphery of the at least one photovoltaic module; and
at least one photovoltaic source circuit including:
at least one photovoltaic source circuit positive terminal and at least one photovoltaic source circuit negative terminal disposed on the periphery of the at least one photovoltaic module;
wherein (i) the at least one photovoltaic module positive terminal is configured for connection with the at least one photovoltaic source circuit negative terminal and (ii) the at least one photovoltaic module negative terminal is configured for connection with the at least one photovoltaic source circuit positive terminal.

11. The photovoltaic assembly of claim 10, wherein the periphery of the at least one photovoltaic module comprises a first side and a second, opposing side; and wherein the at least one positive terminal is disposed on the first side and the at least one negative terminal is disposed on the second, opposing side.

12. The photovoltaic assembly of claim 10, wherein the at least one positive terminal and the at least one negative terminal are disposed on opposing corners of periphery of the at least one photovoltaic module.

13. The photovoltaic assembly of claim 10, wherein:
the at least one positive terminal comprises two positive terminals, each positive terminal being disposed in corners on the first side of the periphery of the at least one photovoltaic module; and
the at least one negative terminal comprises two negative terminals, each negative terminal being disposed in corners on the second, opposing side of the periphery of the at least one photovoltaic module.

14. (canceled)

15. The photovoltaic assembly of claim 10, further comprising:
a perimeter positive bus connecting the at least one positive terminals; and
a main positive bus connecting the plurality of photovoltaic cells to the perimeter positive bus.

16. The photovoltaic assembly of claim 15, further comprising:
a perimeter negative bus connecting the at least one negative terminals; and
a main negative bus connecting the plurality of photovoltaic cells to the perimeter negative bus.

17. The photovoltaic assembly of claim 10, further including diode disposed between, and connecting, the main positive bus and the main negative bus.

18. The photovoltaic assembly of claim 10, further comprising:
at least one photovoltaic module positive terminal housing configured to enclose the at least one positive terminal; and
at least one photovoltaic module negative terminal housing configured to enclose the at least one negative terminal.

19. The photovoltaic assembly of claim 18, further comprising:
at least one photovoltaic source circuit positive terminal housing configured to enclose the at least one photovoltaic source circuit positive terminal; and
at least one photovoltaic source circuit negative terminal housing configured to enclose the at least one photovoltaic source circuit negative terminal;
wherein (i) the at least one photovoltaic source circuit positive terminal housing is configured to mate with the at least one photovoltaic module negative terminal housing, and (ii) the at least one photovoltaic source circuit negative terminal housing is configured to mate with the at least one photovoltaic module positive terminal housing.

20. A photovoltaic assembly, comprising:
at least one photovoltaic module including:
at least one photovoltaic module positive terminal disposed on a first side;
at least one positive terminal housing configured to enclose the at least one positive terminal;
at least one photovoltaic module negative terminal disposed on a second, opposing side;
at least one negative terminal housing configured to enclose the at least one negative terminal; and
at least one photovoltaic source circuit comprising a wire, the wire including:
at least one photovoltaic source circuit positive terminal disposed on a first side;
at least one photovoltaic source circuit negative terminal disposed on a second, opposing side;
at least one photovoltaic source circuit positive terminal housing configured to enclose the at least one photovoltaic source circuit positive terminal; and
at least one photovoltaic source circuit negative terminal housing configured to enclose the at least one photovoltaic source circuit negative terminal;
wherein (i) the at least one photovoltaic source circuit positive terminal housing is configured to mate with the at least one photovoltaic module negative terminal housing, and (ii) the at least one photovoltaic source circuit negative terminal housing is configured to mate with the at least one photovoltaic module positive terminal housing; and
wherein (i) the at least one photovoltaic module positive terminal is configured for connection with the at least one photovoltaic source circuit negative terminal and (ii) the at least one photovoltaic module negative terminal is configured for connection with the at least one photovoltaic source circuit positive terminal.

21. The photovoltaic module of claim 9, wherein the photovoltaic module and the at least one positive terminal housing and the at least one negative terminal housing are configured to prevent accidental contact with the at least one positive terminal and the at least one negative terminal.

22. The photovoltaic assembly of claim 18, wherein the photovoltaic module and the at least one photovoltaic module positive terminal housing and the at least one photovoltaic module negative terminal housing are configured to prevent direct connection of the photovoltaic module terminals of the same polarity.
